(19) United States
(12) Patent Application Publication
(10) Pub. No.: US 2026/0271239 A1
(43) Pub. Date: Sep. 10, 2026

(54) VAPOR CHAMBER FOR DATA CENTER COOLING

(71) Applicant: NVIDIA Corp., Santa Clara, CA (US)

(72) Inventors: John Franz, Tomball, TX (US); Tahir Cader, Spokane, WA (US); David Haley, Beaverton, OR (US); Matthew Slaby, Beaverton, OR (US); Elad Mentovich, Tel Aviv (IL)

(73) Assignee: NVIDIA Corp., Santa Clara, CA (US)

(21) Appl. No.: 19/069,519

(22) Filed: Mar. 4, 2025

(51) Int. Cl. H05K 7/20

(52) U.S. Cl. CPC H05K 7/20609; H05K 7/20254; H05K 7/20272; H05K 7/2039; H05K 7/20654

(57) ABSTRACT

Cold plate embodiments utilizing a vapor chamber formed with a vapor conduit and top and bottom heat exchangers that direct coolant across surfaces of the vapor chamber to conduct heat away from a device to cool, such as an integrated circuit. The cold plate may receive pumped coolant via multiple low-profile inlet ports, and the coolant may exit the cold plate via multiple low-profile outlet ports.

### BACKGROUND

The power and cooling requirements of large integrated circuit packages, such as graphics processing units (GPUs) and central processing units (CPUs) continues to increase. However the volume available to implement the cooling surface area of liquid cooled cold plates has not increased commensurately, and on some machine platforms has actually decreased.

Mechanisms to increase the cooling capacity of liquid cold plates include increasing the planar dimensions of the cold plate, increasing the density of the micro channel fin array in the cold plate, increasing heat transfer capacity by pumping more fluid through the cold plate, or some combination of these approaches.

Increasing the planar dimensions of the cold plate is often challenging due to lack of space to expand the structure in its deployed configuration. Increasing the density of the micro channel fin array may run up against manufacturing constraints and physical effects such as high pressure drop and risks of clogging the cold plate. Pumping more fluid through the cold plate may be impractical due to the pump limitations or due to impact on energy consumption and plumbing system reliability.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates an aspect of the subject matter in accordance with one embodiment.

FIG. 2 illustrates an aspect of the subject matter in accordance with one embodiment.

FIG. 3 depicts a conceptual view of a cooling apparatus mounted on an integrated circuit in accordance with an embodiment.

FIG. 4A depicts a side view of a vapor chamber and micro-channel arrays in accordance with an embodiment.

FIG. 4B depicts a perspective view of a vapor chamber and micro-channel arrays in accordance with an embodiment..

FIG. 4C depicts a top view of a vapor chamber and micro-channel arrays in accordance with an embodiment.

FIGS. 4D and 4E depict additional aspects of the micro-channel arrays and vapor chamber in accordance with an embodiment.

FIG. 4E illustrates an aspect of the subject matter in accordance with an embodiment.

FIG. 5A depicts a perspective view of a cooling apparatus in accordance with an embodiment.

FIG. 5B depicts a perspective view of a vapor chamber utilized with a cooling apparatus in accordance with an embodiment.

FIG. 6A depicts a side view of a cooling apparatus in accordance with an embodiment.

FIG. 6B depicts a bottom view of a cooling apparatus in accordance with an embodiment.

FIG. 6C depicts a top view of a cooling apparatus in accordance with an embodiment.

FIG. 7A depicts a cut-away perspective view of a cooling apparatus in accordance with an embodiment.

FIG. 7B depicts a cut-away perspective view of a cooling apparatus in accordance with an embodiment.

FIG. 8A depicts a side view of a cooling apparatus with sectional view planes in accordance with an embodiment.

FIG. 8B depicts a perspective view of section A of a cooling apparatus in accordance with an embodiment.

FIG. 8C depicts a perspective view of section B of a cooling apparatus in accordance with an embodiment.

FIG. 8D depicts a perspective view of section C of a cooling apparatus in accordance with an embodiment.

FIG. 8E depicts a perspective view of section D of a cooling apparatus in accordance with an embodiment.

FIG. 8F depicts a perspective view of section E of a cooling apparatus in accordance with an embodiment.

FIG. 8G depicts a perspective view of section F of a cooling apparatus in accordance with an embodiment.

FIG. 8H depicts a perspective view of section G of a cooling apparatus in accordance with an embodiment.

FIG. 9 depicts an exploded view of a cold plate apparatus in accordance with an embodiment.

FIG. 10 depicts a parallel processing unit in accordance with an embodiment.

FIG. 11 depicts an example of an integrated circuit with which the disclosed cooling mechanisms may be utilized, in accordance with an embodiment.

FIG. 12 depicts a computing system in accordance with an embodiment.

FIG. 13 depicts an exemplary data center 1300 in which the disclosed cooling apparatus may be deployed, in accordance with at least an embodiment.

FIG. 14 illustrates an aspect of the subject matter in accordance with one embodiment.

### DETAILED DESCRIPTION

Printed circuit boards (PCBs) enable the integration of multiple electronic components, such as separately packaged integrated circuits (ICs), capacitors, resistors, voltage regulators, and the like, into a single compact assembly. Such assemblies oftentimes are referred to as printed circuit board assemblies (PCBAs) and are used in a wide range of communication and computing implementations, including, without limitation, mobile phones, laptop computers, desktop computers, and server machines.

In high-performance implementations, such as graphics cards and server machines, certain electronic components of a PCBA can generate significant heat during operation. To prevent over-heating, the generated heat has to be transferred away from the PCBA. Accordingly, in practice, many high-performance PCBAs include, or are coupled, to a heat sink, cold plate, or other thermal solution that greatly increases the amount of heat transfer away from the PCBA. Typically, the thermal solution is a heat transfer apparatus that is mounted on a PCBA such that a cooling surface of the thermal solution is coupled to a heat-generating component of the PBCA, such as a high-power IC. In such a configuration, the thermal solution transfers heat directly away from the heat-generating component.

Many heat-generating components that are included in PCBAs are very fragile and can be damaged when coupled to a thermal solution during assembly. For example, PCBAs often include packaged ICs, such as a graphics processing unit (GPU) or a central processing unit (CPU). A CPU or GPU is typically a single, large processor die that is a fraction of a millimeter thick and includes millions of microscopic transistors. Because of the relatively large surface area and limited thickness of these types of processor dies, even a slight deflection of, or accidental contact with, a given die when attaching the thermal solution can cause substantial damage to the processor die. Further, modern processor dies oftentimes are packaged with other, even more delicate ICs, such as high-bandwidth memory (HBM) devices. Consequently, packages for processing dies and other ICs are commonly “lidded” packages, which include a lid that fully encases and protects the various IC dies within the package.

In at least one embodiment, a datacenter liquid cooling system is disclosed. In at least one embodiment, this datacenter cooling system addresses heat features in associated computing or datacenter devices, such as in graphics processing units (GPUs), in switches, in dual inline memory module (DIMMs), or central processing units (CPUs). In at least one embodiment, these components may be referred to herein as high heat density computing components. Furthermore, in at least one embodiment, an associated computing or datacenter device may be a processing card having one or more GPUs, switches, or CPUs thereon. In at least one embodiment, each of GPUs, switches, and CPUs may be a heat generating feature of a computing device. In at least one embodiment, a GPU, a CPU, or a switch may have one or more cores, and each core may be a heat generating feature.

Cold plate embodiments are disclosed utilizing a vapor chamber. The disclosed cold plate designs may be constructed with a form factor compatible with conventional cold plate installations.

In at least one embodiment, a cold plate includes adjustable fins forming microchannels for fluid to flow through. In at least one embodiment, fins in a cold plate enable transfer of heat from at least one associated computing device to a fluid flowing through microchannels formed between multiple fins. In at least one embodiment, fins of a cold plate are dynamically and adjustable in real time to allow transfer of more heat from at least one computing device to a fluid that flows through a cold plate having fins. In at least one embodiment, such fins may be adjusted by a processor or processorless system based in part on a temperature determined, such as sensed, for a cold plate. In at least one embodiment, a temperature may be associated with at least one computing device, a workload of at least one computing device, or a fluid at different time periods and at an entry, and at an egress of a cold plate. In at least one embodiment, a processorless system may rely on a thermal property of at least two materials used to form fins for a cold plate so that such fins may react without a processor to cause exposure of more surface area to a fluid. In at least one embodiment, such fins may include an overlapping portion that may be caused to be exposed by action of a control mechanism or by properties of at least two materials associated together to form a fin.

In at least one embodiment, multiple fins form microchannels for fluid to flow therebetween. In at least one embodiment, such fins are able to actively or passively react to thermal feedback by a modification of microchannels to enable fluid to absorb more heat from at least one computing device. In at least one embodiment, an active reaction may be enabled by at least one processor that can expose more surface area of such fins by expanding an overlapping portion of such fins. In at least one embodiment, a passive reaction may be enabled by a thermal property of materials associated together to form each fin of such fins that allows such fins to expand.

In at least one embodiment, static cold plates used for liquid cooling of GPU, CPU, Switches, and other high heat density components may have static microchannels allowing flow of fluid therein to remove heat from such heat dissipating components in datacenters. In at least one embodiment, static cold plates incorporate design and methods for heat removal that are not related to or reactive to heat density or heat dissipation by computing components. In at least one embodiment, some cold plates may have varying thermal behaviors depending on computational, environmental and other attributes that require a dynamic behavior for achieving optimum heat removal capability for available resources in a liquid cooled environment.

In at least one embodiment, channels may be formed by skiving after forming blocks of one or more materials depending on a processor or processorless application. In at least one embodiment, microchannels may be formed at about 300 microns spacing therebetween. In at least one embodiment, a heat map may be determined for at least one associated computing device. In at least one embodiment, such a heat map may be used to reconfigure or restate a cold plate by reconfiguring or restating channels within it. In at least one embodiment, such configuration or state changes increase fluid flow rate as well as surface area of fins exposed to such fluid. In at least one embodiment, an amount of fluid may be half of a volume or flow rate in heated areas versus in other areas of a heat map.

Embodiments in accordance with the disclosed mechanisms provide improved thermal performance enabling higher power devices, support higher flow, and maintain assembly height restrictions.

Utilizing an array of low-profile fluid connection ports, the disclosed mechanisms may provide improved cooling capacity and reduced pressure drops over conventional designs. Maintaining existing fluid flow rate divided across more surface area results in lowering pressure drop. The connection ports may be arranged in a parallel configuration to maintain high fluid volume capability. Increased flow rate without risking high velocity erosion concerns and excessive pressure drop. The disclosed mechanisms may operate with lower pumping power than conventional cold plate designs, or may operate at comparable pumping power with increased fluid flow.

Embodiments in accordance with the disclosed mechanisms may efficiently transport heat generated by an integrated circuit upward to top surfaces of the vapor chamber where additional cooling by circulated fluids is applied. The vapor chamber takes advantage of the volume on the top of the cold plate that has not been cooled before. Most often vapor chambers are constructed flat to take advantage of large XY areas to move heat. However, this use of a vapor chamber is not possible with the limited space that surrounds a GPU or CPU.

In one aspect, an apparatus for cooling integrated circuits includes a vapor chamber comprising a lower portion, and upper portion, and a vapor conduit that enables a flow of vapor via convection from the lower portion to the upper portion (and a return of condensed fluid to the lower portion). Herein, the term “upper” or “top” should be understood to mean that a component or element is disposed at a further distance from a heat source (in the direction of heat flow) than a “lower” or “bottom” or “base” component.

The cooling apparatus may also include a first micro-channel array (more generally, any heat exchanger) thermally coupled to the lower portion of the vapor chamber, and a second micro-channel array thermally coupled to the upper portion of the vapor chamber. Herein, “array” should be understood to mean a regular arrangement of elements, e.g., metal fins, and not necessarily a cell or grid-based configuration. The end result is nearly double the surface area for cooling and dramatically reduced power density as a result of the very efficient heat transport system provided by the VC physics. The two sets of micro-channel array are linked to quickly distribute the thermal load across both the bottom and top zones for cooling. The balanced cooling medium may be delivered to the micro channel sets sequentially or simultaneously.

The vapor chamber may be formed from thermally conductive metal, e.g., copper, into a U-shape. In some embodiments, the micro-channel array utilized in the lower portion of the vapor chamber may have a greater surface area than the surface area of the lower micro-channel array to maximize cooling benefit with direct contact to heat source. The upper micro-channel array may comprise a greater surface area than the surface area lower micro-channel array to allow more space for fluid connections and internal fluid distribution paths.

The cooling apparatus may also include multiple inlet ports each having an ovoid, obround, flattened-rectangle, or other flattened cross-section, and may also include multiple outlet ports also having such flattened cross-sections, thereby enabling an increase in flow capacity.

Other technical features may be readily apparent to one skilled in the art from the following figures, descriptions, and claims.

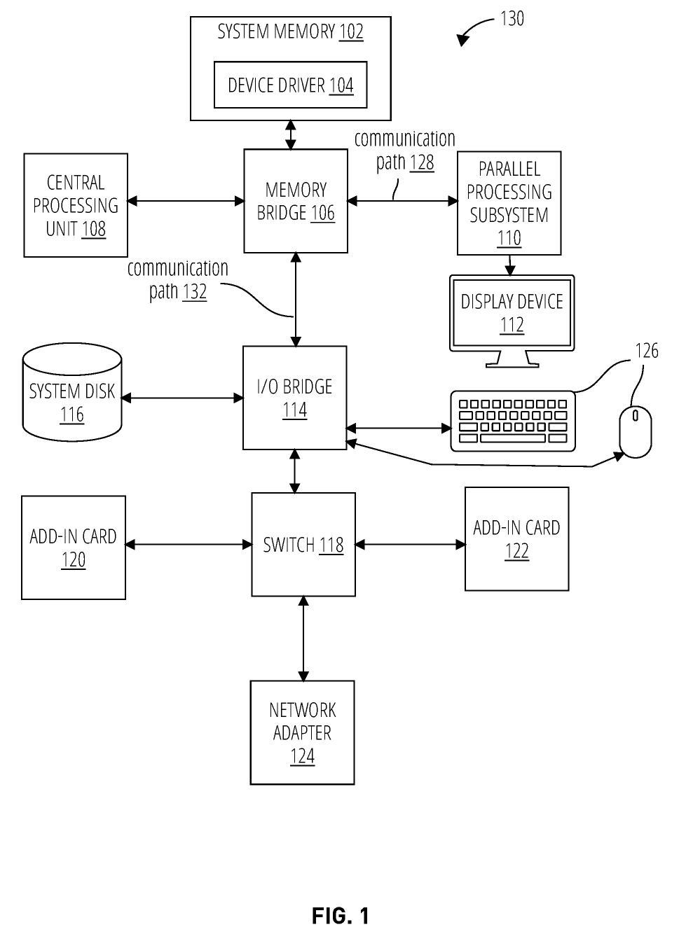

FIG. 1 is a conceptual illustration of a computer system 130 configured to implement one or more aspects of the various embodiments. As shown, computer system 130 includes a central processing unit 108 (CPU) and a system memory 102 communicating via a bus path that may include a memory bridge 106. The central processing unit 108 may include one or more processing cores, and, in operation, the central processing unit 108 may be the master processor of the computer system 130, controlling and coordinating operations of other system components.

System memory 102 may be configured with machine-readable instructions (e.g., software applications) and data for execution by the central processing unit 108. The central processing unit 108 may for example execute software applications and optionally an operating system.

Memory bridge 106, which may for example be a Northbridge chip, is coupled via a bus or other communication path 132 (e.g., a HyperTransport link) to an input/output bridge 114. The input/output bridge 114, which may be, e.g., a Southbridge chip, receives user input from one or more user input devices 126 (e.g., keyboard, mouse, joystick, digitizer tablets, touch pads, touch screens, still or video cameras, motion sensors, and/or microphones) and forwards the input to the central processing unit 108 via the memory bridge 106.

A parallel processing subsystem 110 is coupled to memory bridge 106 via a bus or other communication path 128 (e.g., a PCI Express, Accelerated Graphics Port, or HyperTransport link). In one embodiment parallel processing subsystem 110 comprises a graphics subsystem that includes at least one graphics processing unit (GPU) and graphics memory. The graphics memory may include a display memory (e.g., a frame buffer) used for storing pixel data for each pixel of an output image. The graphics memory may be integrated in the same device as the GPU, connected as a separate device with the GPU, and/or implemented within system memory 102.

The parallel processing subsystem 110 may output pixels to a display device 112 (e.g., a screen or conventional CRT, plasma, OLED, SED or LCD based monitor or television). Additionally, the parallel processing subsystem 112 may output pixels to other devices, such as printers or other devices adapted to reproduce computer generated images on physical media.

The parallel processing subsystem 110 may provide pixels to the display device 112 using an analog or digital signal. In various embodiments, a graphical user interface is displayed to one or more users via the display device 112, and the one or more users can input data into and receive visual output from the graphical user interface.

A system disk 116 may also be coupled to the input/output bridge 114 and may be configured to store content and applications and data for use by central processing unit 108 and parallel processing subsystem 110. The system disk 116 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 118 provides connections between the input/output bridge 114 and other components such as a network adapter 124 and various add-in cards 120, 122. The network adapter 124 enables the computer system 130 to communicate with other systems via an electronic communications network, and may include wired or wireless communication over local area networks and wide area networks such as the Internet.

The computer system 130 may comprise other components (not shown), including Universal Serial Bus (USB) or other port connections, recording devices, and the like, and these may also be connected to the input/output bridge 114. For example, an audio processor may be used to generate analog or digital audio output from instructions and/or data provided by central processing unit 108, system memory 102, or system disk 116.

Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, the parallel processing subsystem 110 incorporates circuitry optimized for graphics and video processing, including, for example, video output circuitry, and constitutes a graphics processing unit (GPU). In another embodiment, the parallel processing subsystem 110 incorporates circuitry optimized for general purpose processing. In yet another embodiment, the parallel processing subsystem 110 may be integrated with one or more other system elements, such as the memory bridge 106, central processing unit 108, and input/output bridge 114 to form a system on chip (SoC). In still further embodiments, the parallel processing subsystem 110 is omitted and software executed by the central processing unit 108 performs (emulates) the functions of the parallel processing subsystem 110.

Pixel data may be provided to parallel processing subsystem 110 directly from the central processing unit 108. In some embodiments, instructions and/or data representing a scene are provided to a render farm or a set of server computers, each similar to the computer system 130 in some respects, via the network adapter 124 or the system disk 116. The render farm generates one or more rendered images of the scene using the provided instructions and/or data. These rendered images may be stored on computer-readable media in a digital format and optionally returned to the computer system 130 for display. Similarly, stereo image pairs processed by the parallel processing subsystem 110 may be output to other systems for display, stored by the system disk 116, or stored on non-volatile computer-readable media in a digital format.

Alternatively, the central processing unit 108 may provide the parallel processing subsystem 110 with data and/or instructions defining the desired output images, from which the parallel processing subsystem 110 generates the pixel data of one or more output images, including characterizing and/or adjusting the offset between stereo image pairs. The data and/or instructions defining the desired output images can be stored in the system memory 102 or graphics memory within the parallel processing subsystem 110.

In an embodiment, the parallel processing subsystem 110 comprises 3D rendering capabilities for generating pixel data for output images from instructions and data defining the geometry, lighting shading, texturing, motion, and/or camera parameters for a scene. The parallel processing subsystem 110 may further include one or more programmable execution units capable of executing shader programs, tone mapping programs, and the like.

In some embodiments, the central processing unit 108 or the parallel processing subsystem 110 may be replaced with or supplemented by any technically feasible form of processing device configured process data and execute program code. Such a processing device could be, for example, be a graphics processing unit (GPU), an application-specific integrated circuit (ASIC), a field-programmable gate array (FPGA), and so forth. In various embodiments any of the operations and/or functions described herein may be performed by central processing unit 108, the parallel processing subsystem 110, or one or more other processing devices or any combination of these different processors.

The central processing unit 108, a render farm, and/or the parallel processing subsystem 110 may employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, computer system 130 may or may not include other elements shown in FIG. 1. The system memory 102 and/or other memory units or devices in computer system 130 may include instructions that, when executed, cause a robot or robotic device comprising or controlled by the computer system 130 to perform one or more operations, steps, tasks, or the like.

It will be appreciated that the computer system 130 depicted is illustrative and that variations and modifications are possible. The connection topology, including the number and arrangement of bridges, may be modified as desired. For instance, in some embodiments, the system memory 102 may coupled to the central processing unit 108 directly rather than through a bridge, and other devices communicate with system memory 102 via memory bridge 106 and central processing unit 108. In other alternative topologies the parallel processing subsystem 110 may be coupled to the input/output bridge 114 or directly to the central processing unit 108, rather than to the memory bridge 106. In still other embodiments, the input/output bridge 114 and the memory bridge 106 might be integrated into a single chip.

Some of the depicted components may be optional in some embodiments. For example, any number of add-in cards or peripheral devices might be supported. In some embodiments, the switch 118 is eliminated, and the network adapter 124 and the add-in cards 120, 122 may connect directly to the input/output bridge 114.

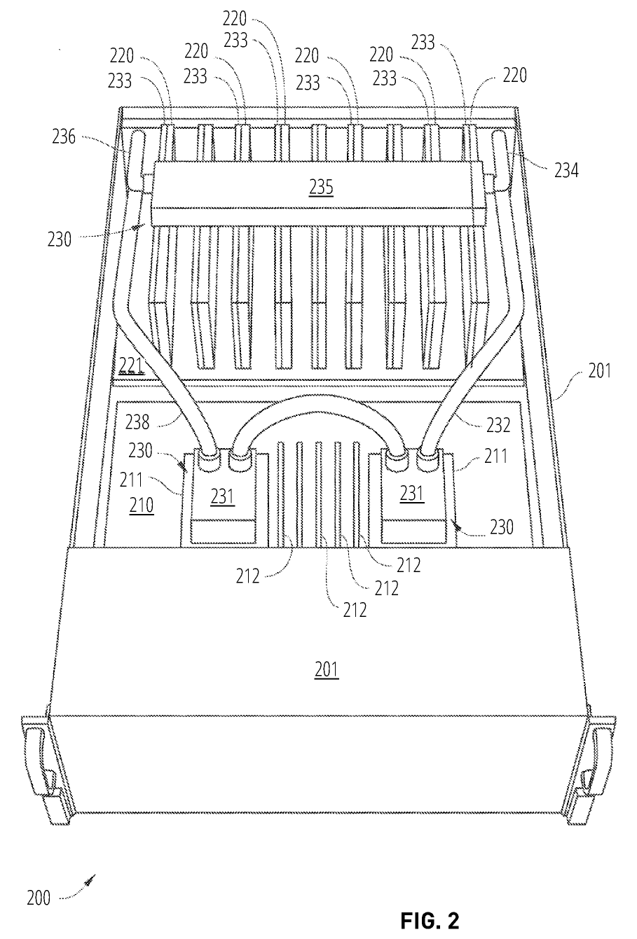

FIG. 2 illustrates an exemplar implementation of a computer system configured as a server machine 200 that provides data, services, programs, computing resources, and/or other resources to a plurality of client computers (not shown) over a network. For example, in some embodiments, the server machine 200 may be configured as a rack-mounted system installed in a server rack. The server machine 200 may include a server motherboard 210 and/or one or more graphics cards 220 disposed within an enclosure 201.

The motherboard 210 enables communication between various electronic components of server machine 200, such as one or more central processing units 211 and memory devices 212. In some embodiments, the memory devices 212 comprise dual in-line memory modules (DIMMs) and/or single in-line memory modules (SIMMs). In the embodiment depicted in FIG. 2, the server motherboard 210 comprises two central processing units 211 and is configured with a plurality of memory devices 212. Alternatively, in some embodiments, the server motherboard 210 comprises more than or fewer than two central processing units 211.

The server motherboard 210 may comprise a printed circuit board assembly (PCBA) that is configured according to various embodiments described herein.

Each graphics card 220 may comprise at least one GPU (not shown) and may be configured to enable the server machine 200 to perform diverse artificial intelligence (AI), high-performance computing (HPC), and accelerated computing workloads. In the embodiment depicted in FIG. 2, server machine 200 comprises nine graphics cards 220, for example mounted on a backplane 221. Alternatively, in some embodiments, the backplane 221 may comprise more than or fewer than nine graphics cards 220 mounted thereon. In some embodiments, each graphics card 220 may comprise a printed circuit board assembly (PCBA) that is configured according to various embodiments described herein.

Alternatively or additionally, in some embodiments, server machine 200 may comprise one or more cooling air inlets and cooling fans (not shown). For example, in some embodiments, cooling air inlets and cooling fans enable air cooling of electronic components mounted on server motherboard 210, graphics cards 220, and/or thermal mitigation components 230.

To facilitate cooling of high-performance components of server motherboard 210 and/or graphics cards 220, the server machine 200 further includes one or more thermal mitigation component 230. By directly cooling the server motherboard 210 and graphics cards 220, more heat may be transferred from the server motherboard 210 and graphics cards 220 and higher computing performance thereby may be realized, for example via operating processors at higher speeds. Alternatively or additionally, the operational lifetime of various components of the server motherboard 210 and the graphics cards 220 may be extended by cooling such components below their nominal operating temperatures.

Each thermal mitigation component 230 comprises a heat transfer apparatus or device that is coupled to a PCBA of the server machine 200, and facilitates heat transfer away from one or more heat-generating electronic devices included in the PCBA. Examples of thermal mitigation components 230 include air-cooled thermal solutions, such as a heat sink with cooling fins, and water-cooled thermal solutions, such as a cooling plate or water block. In some embodiments, a thermal mitigation component 230 that is coupled to a PCBA of the server machine 200 may further include a phase change device, such as a vapor chamber, which spreads the heat generated by a PCBA over a wider surface area via an evaporator and condenser.

In the embodiment depicted in FIG. 2, a separate water-cooled thermal mitigation component 230 such as a cold plate 231 is coupled to each central processing unit 211. Each cold plate 231 is coupled to a particular central processing unit 211, and is configured to cool the particular central processing unit 211 by the flow of water or other cooling liquid through the cold plate 231.

In the depicted example, an intake cooling liquid line 232 directs a cooling liquid into the server machine 200, through each cold plate 231, and out of server machine 200 via an outtake cooling liquid line 238, for example to a water chiller or other external heat exchange system.

In addition, in the embodiment depicted in FIG. 2, a separate water-cooled thermal mitigation component 230 such as a full-coverage cold plate 233 is also coupled to each graphics card 220. Each full-coverage cold plate 233 is coupled to a particular graphics card 220, and is configured to cool the particular graphics card 220 by the flow of water or other cooling liquid through cold plate 233. Unlike the cold plates 231, the full-coverage cold plates 233 may be configured to cool multiple heat-generating electronic devices of a graphics card 220 when coupled thereto.

As depicted, an intake cooling liquid line 234 directs a cooling liquid to a manifold 235 within the server machine 200, and an outtake cooling liquid line 236 directs a cooling liquid from the manifold 235 out of the server machine 200, for example to a water chiller or other external heat exchange system. The manifold 235 is fluidly coupled to the cold plate 233 of each graphics card 220, thereby enabling the liquid cooling of each graphics card 220. In some embodiments, the manifold 235 includes a supply section (not shown) that fluidly couples each cold plate 233 to the intake cooling liquid line 234 and a return section (not shown) that fluidly couples each cold plate 233 to the outtake cooling liquid line 236.

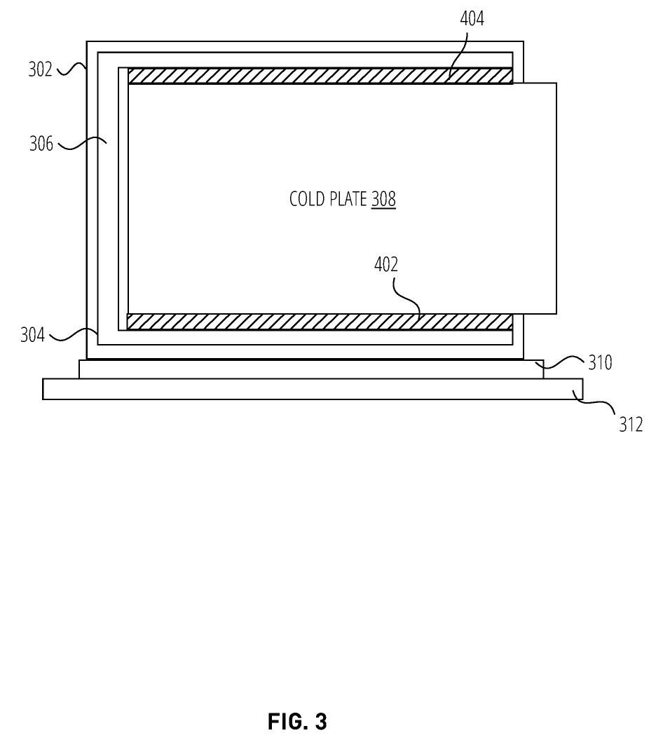

FIG. 3 depicts a conceptual view of a cooling apparatus, e.g., a thermal mitigation component 230, mounted on an integrated circuit in accordance with an embodiment. The system cooling apparatus comprises a vapor chamber 302 comprising an internal volume 304 that includes a vapor conduit 306. In some embodiments the vapor chamber 102 is formed into a U-shape. The U-shape defines a substantially 180 degree bend for vapor passage and condensed fluid transfer.

The exemplary U-profile is just one possible formation of the vapor chamber 302. More generally, the vapor chamber 302 may comprise any shape with multiple levels coupled together with one or more vapor passages. For example, the shape of the vapor chamber 302 may be less curved than in the depicted example, constructed with more right-angled sections. Vapor passages between the levels may in some implementations be formed at multiple locations. The vapor passages may comprise cross sections that cylindrical, rectangular, or other shapes better accommodate cooling performance goals, manufacturing, and/or structural constraints.

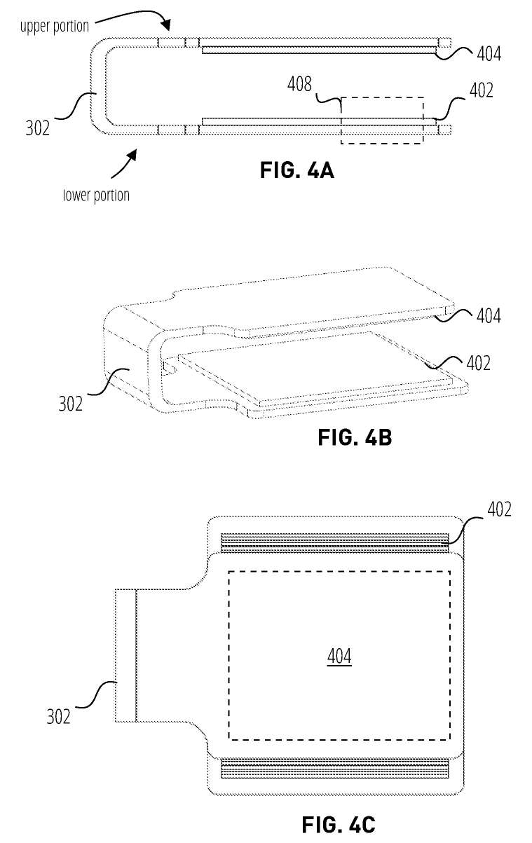

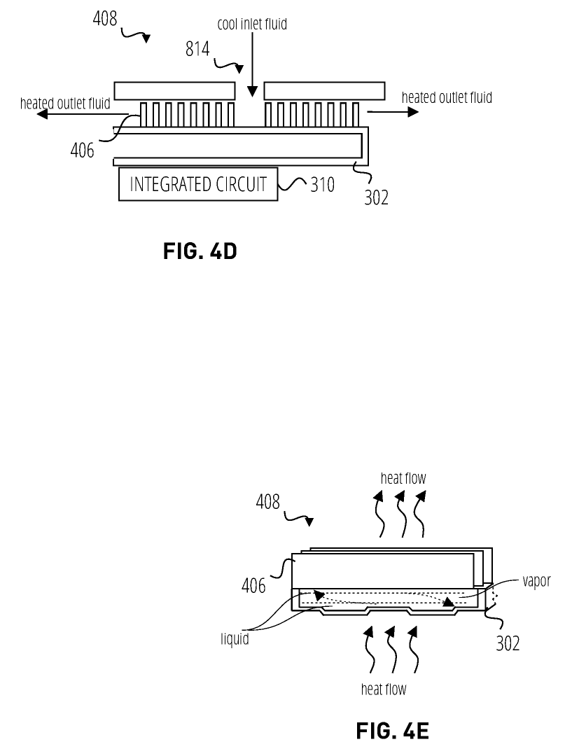

A bottom micro-channel array 402 and a top micro-channel array 404 are mounted on, or manufactured to be integral with, the vapor chamber 302. In some embodiments, the cooling apparatus comprises a cold plate 308 disposed in the cavity of the vapor chamber 302 formed by the U-shape. The cold plate 308 may have a height for example between five and ten millimeters, with an overall height of the assembly, including the vapor chamber 302 and fluid connections, being constrained to around 20mm. The cooling apparatus is mounted above a heat-generating integrated circuit 310 (e.g., a high-performance data processor) affixed either directly or via a socket (not depicted) to a mounting substrate 312. FIGS. 4A-4C depict embodiments of a vapor chamber and micro-channel arrays in various views.

The micro-channel arrays may in some embodiments comprise integral fin features of the vapor chamber 302 that are skived or bonded to the metal (e.g., copper) structure of the vapor chamber 302 such that thermal resistance is near zero. The fin features are separated by gaps, and the cooling fluid travels into the gaps between the fins to take on and extract heat. The dimensions of the fin gaps may be configured to reduce clogging risk and conform to practical manufacturing processes. Utilizing the disclosed vapor chamber mechanisms, fin gap spacing may be maintained at dimensions practical for manufacturing, e.g., 100-150 microns, while substantially increasing the surface area for heat exchange. The micro-channel arrays may enable inlet and exit flow from an external pumping device.

In the depicted example, the integrated circuit 310 is in direct thermal contact with the lower portion of the vapor chamber 302. In the lower portion of the vapor chamber 302, heat from the integrated circuit 310 vaporizes liquid in the vapor chamber 302. The vapor rises and meets the top surface of the lower portion of vapor chamber 302, where heat from the vapor is conducted into the bottom micro-channel array 402. The heat is further conducted into fluid pumped through the fins of the bottom micro-channel array 402 and carried to the internal fluid outlets 702, where it exits the cooling apparatus via the external fluid outlet ports 704.

Vapor from the lower portion of the vapor chamber 302 also enters the vapor conduit 306, where it meets the top surface of the upper portion of the vapor chamber 302. Here heat from the vapor is conducted into the top micro-channel array 404. The heat is further conducted into fluid pumped through the fins of the top micro-channel array 404 and carried to the internal fluid outlets 702, where it exits the cooling structure via the external fluid outlet ports 704. Fluid formed from condensed vapor in the upper portion of the vapor chamber 302 may flow down the vapor conduit 306 to the lower portion of the vapor chamber 302, where it may be vaporized again by the heat from the integrated circuit 310, repeating the heat flow cycle.

The top micro-channel array 404 and bottom micro-channel array 402 may comprise heat dissipating elements 406 such as metallic fins. Heat flow from the integrated circuit 310 is transferred into liquid in the vapor chamber 302. The liquid vaporizes, heat is transferred from the vapor to the heat dissipating elements 406, and the vapor condenses into liquid again, perpetuating the cooling cycle.

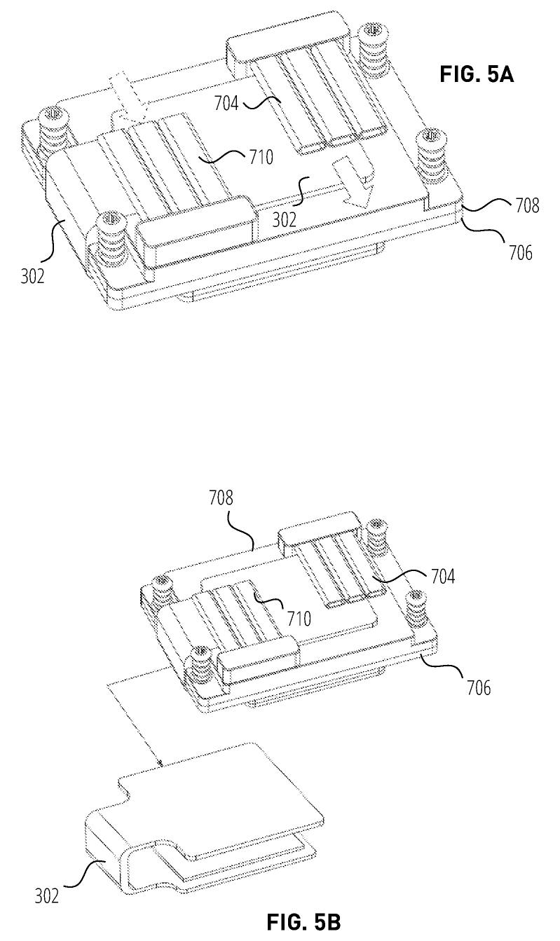

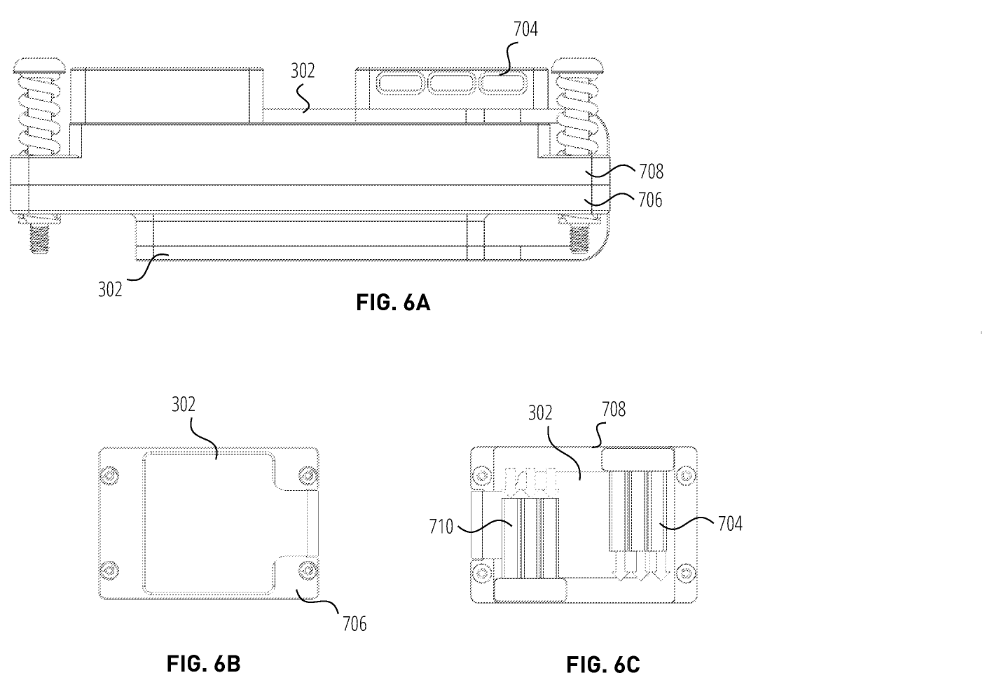

FIG. 5A depicts a perspective view of a cooling apparatus in accordance with an embodiment, and FIG. 5B depicts a vapor chamber utilized in conjunction therewith. The cooling apparatus comprises a base manifold 706 and a top manifold 708 comprising external fluid inlet ports 710 for pumping coolant into the apparatus, and external fluid outlet ports 704 for egress of the heated cooling fluid. These features are depicted in additional views in FIGS. 6A-6C.

The external fluid inlet ports 710 and the external fluid outlet ports 704 comprise pluralities of flattened pipes (e.g., ovoids), rather than the singular rounded ports used in some conventional designs, to reduce pressure drop and lower the profile to fit within existing cold plate design limits. Other flattened shapes may be utilized for the external fluid inlet ports 710 and/or external fluid outlet ports 704, such as rectangular cross-sections with a width several times more extensive than their height.

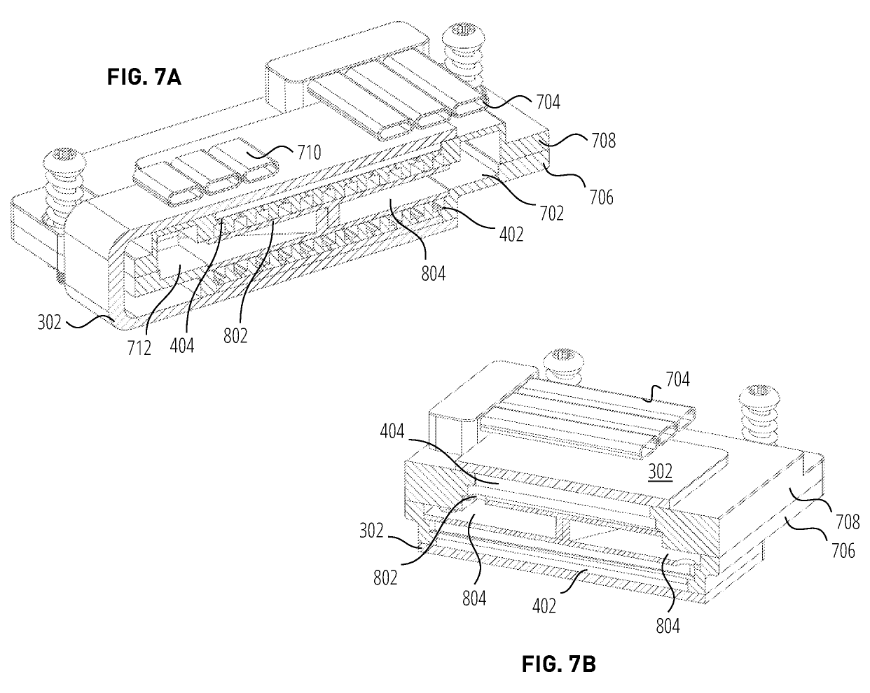

FIGS. 7A and 7B depict cut-away perspective views of a cooling apparatus in accordance with an embodiment, depicting a relative arrangement of the top manifold 708, base manifold 706, vapor chamber 302, bottom micro-channel array 402, top micro-channel array 404, external fluid outlet ports 704, and external fluid inlet ports 710.

The cooling apparatus further comprises an internal fluid inlet 712 that receives coolant from the external fluid inlet ports 710 and an internal fluid outlet 702 that channels heated fluid to the external fluid outlet ports 704. A flow plate 802 distributes fluid to and from the top micro-channel array 404, and a bottom flow plate 804 distributes fluid to and from the bottom micro-channel array 402.

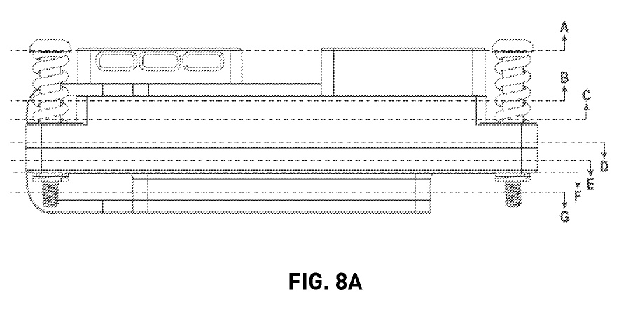

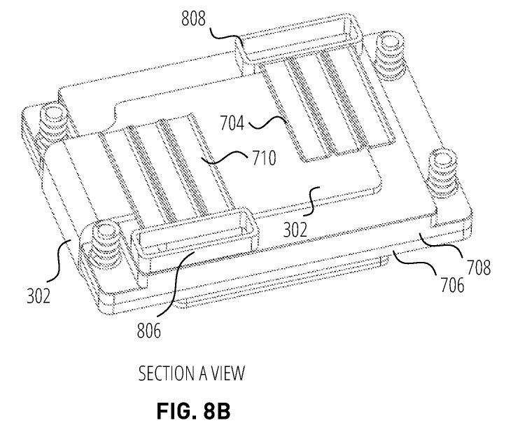

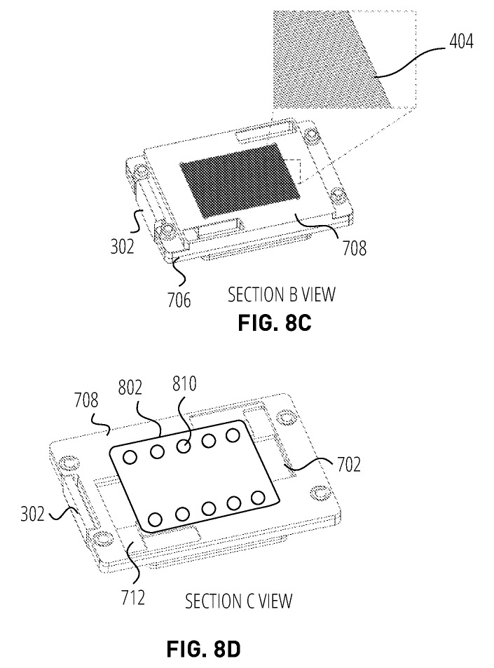

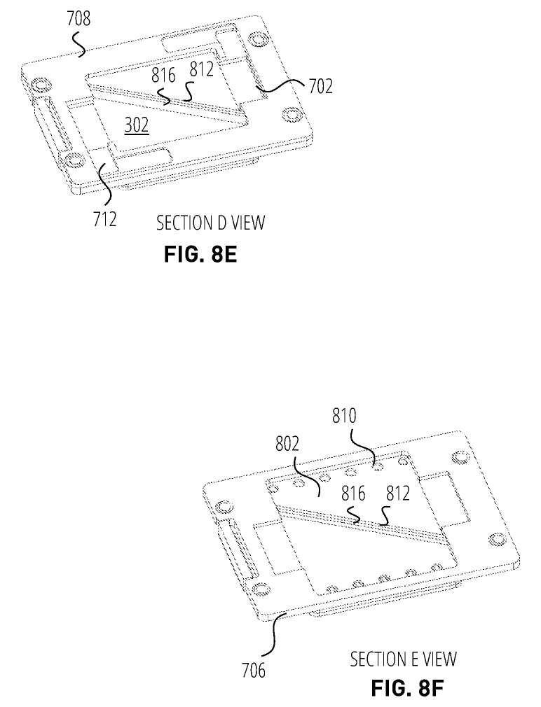

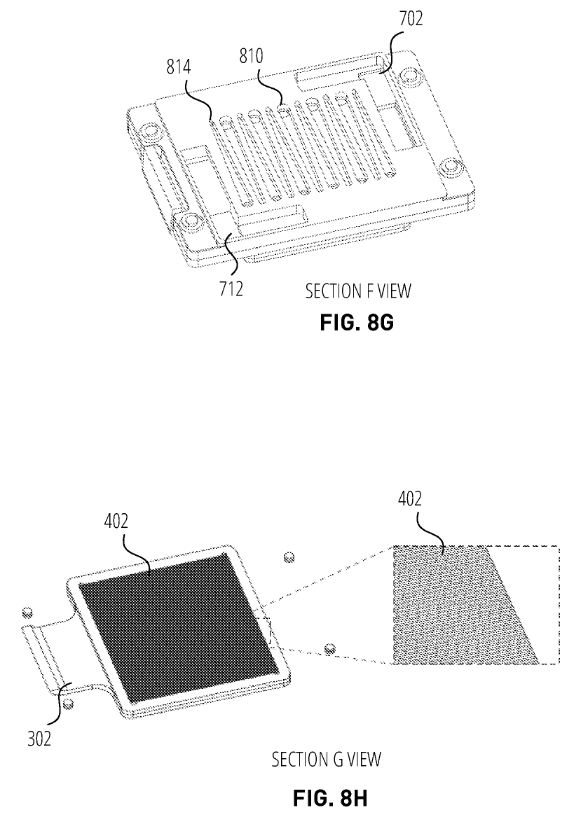

FIG. 8A depicts a side view of a cooling apparatus with sectional view planes in accordance with an embodiment. FIGS. 8B-8H depict perspective views through the various sectional planes of the cooling apparatus.

FIG. 8B depicts a view of Section A, showing a relative configuration of the vapor chamber 302, base manifold 706, and top manifold 708. The top manifold 708 comprises an inlet manifold 806 to collect fluid from the external fluid inlet ports 710 and an outlet manifold 808 to collect fluid for the external fluid outlet ports 704. The external fluid inlet ports 710 and external fluid outlet ports 704 each comprise a cross-sections that that does not extend beyond a height of the inlet manifold 806 or outlet manifold 808, respectively. The “height” of the manifolds is the extent to which the manifolds extend from the upper portion of the vapor chamber 302.

FIG. 8C depicts (Section B) a cutaway in the top manifold 708 revealing a portion of the top micro-channel array 404.

FIG. 8D depicts (Section C) a flow plate 802 comprising flow-through holes 810.

The flow-through holes 810 comprise inlet and exit holes. The flow divider 812 creates a flow barrier in the fluid chamber (the area between the external fluid inlet port 710 and the internal fluid outlet 702). Fluid from the external fluid inlet port 710 passes through the inlet manifold 806 into the internal fluid inlet 712. The flow divider 812 urges the flow through half of the flow-through hole 810 along one edge of the chamber structure. Before the fluid exits the chamber via the outlet manifold 808, it traverses the tapered flow channels 814 and the top micro-channel array 404, collecting heat from the vapor chamber 302, before exiting via the neighboring tapered flow channels 814. The fluid then reenters the the chamber area , from which it enters the internal fluid outlet 702 and traverses upward through the outlet manifold 808 and then exits the external fluid outlet port 704.

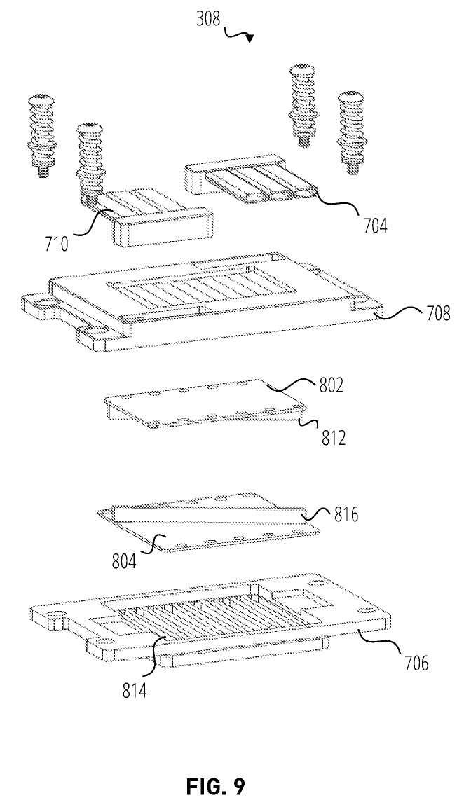

As depicted in FIG. 9, in an embodiment a bottom flow plate 804 comprising a bottom flow divider 816 may be utilized to complement the flow plate 802 and flow divider 812.

FIG. 8E depicts (Section D) the vapor chamber 302, top manifold 708, internal fluid inlet 712, internal fluid outlet 702, and flow dividers in additional aspects.

FIG. 8F depicts (Section E) the base manifold 706, flow plate 802, flow-through holes 810, and flow divider 812 in additional aspects.

FIG. 8G depicts (Section F) the flow channels 814, the flow-through holes 810, and the flow divider 812 in additional aspects.

FIG. 8H (Section G) depicts an embodiment of the bottom micro-channel array 402 of the vapor chamber 302 in greater detail.

FIG. 9 depicts an exploded view of a cold plate apparatus in accordance with an embodiment. A relative configuration of the cold plate 308, external fluid outlet ports 704, top manifold 708, base manifold 706, external fluid inlet ports 710, flow plate 802, flow divider 812, bottom flow plate 804, bottom flow divider 816, and flow channels 814 are depicted.

The cooling mechanisms disclosed herein may be utilized in or with computing devices utilizing one or more graphic processing unit (GPU) and/or general purpose data processor (e.g., a 'central processing unit or CPU). Exemplary systems and integrated circuits will now be described that may be configured in conjunction with the cooling mechanisms disclosed herein.

The following description may use certain acronyms and abbreviations as follows:

"DPC" refers to a "data processing cluster";

"GPC" refers to a "general processing cluster";

"I/O" refers to a "input/output";

"L1 cache" refers to "level one cache";

"L2 cache" refers to "level two cache";

"LSU" refers to a "load/store unit";

"MMU" refers to a "memory management unit";

"MPC" refers to an "M-pipe controller";

"PPU" refers to a "parallel processing unit";

"PROP" refers to a "pre-raster operations unit";

"ROP" refers to a "raster operations";

"SFU" refers to a "special function unit";

"SM" refers to a "streaming multiprocessor";

"Viewport SCC" refers to "viewport scale, cull, and clip";

"WDX" refers to a "work distribution crossbar"; and

"XBar" refers to a "crossbar".

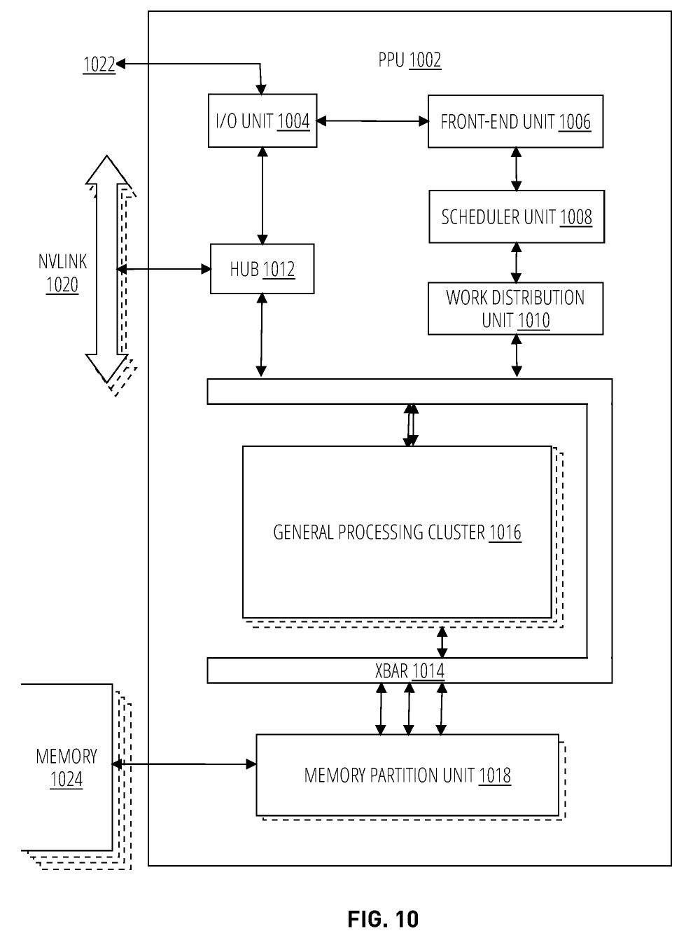

FIG. 10 depicts a parallel processing unit 1002, in accordance with an embodiment. In an embodiment, the parallel processing unit 1002 is a multi-threaded processor that is implemented on one or more integrated circuit devices. The parallel processing unit 1002 is a latency hiding architecture designed to process many threads in parallel. A thread (e.g., a thread of execution) is an instantiation of a set of instructions configured to be executed by the parallel processing unit 1002. In an embodiment, the parallel processing unit 1002 is a graphics processing unit (GPU) configured to implement a graphics rendering pipeline for processing three-dimensional (3D) graphics data in order to generate two-dimensional (2D) image data for display on a display device such as a liquid crystal display (LCD) device. In other embodiments, the parallel processing unit 1002 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more parallel processing unit 1002 modules may be configured to accelerate thousands of High Performance Computing (HPC), data center, and machine learning applications. The parallel processing unit 1002 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 10, the parallel processing unit 1002 includes an I/O unit 1004, a front-end unit 1006, a scheduler unit 1008, a work distribution unit 1010, a hub 1012, a crossbar 1014, one or more general processing cluster 1016 modules, and one or more memory partition unit 1018 modules. The parallel processing unit 1002 may be connected to a host processor or other parallel processing unit 1002 modules via one or more high-speed NVLink 1020 interconnects. The parallel processing unit 1002 may be connected to a host processor or other peripheral devices via an interconnect 1022. The parallel processing unit 1002 may also be connected to a local memory comprising a number of memory 1024 devices. In an embodiment, the local memory may comprise a number of dynamic random access memory (DRAM) devices. The DRAM devices may be configured as a high-bandwidth memory (HBM) subsystem, with multiple DRAM dies stacked within each device. The memory 1024 may comprise logic to configure the parallel processing unit 1002 to carry out aspects of the techniques disclosed herein.

The NVLink 1020 interconnect enables systems to scale and include one or more parallel processing unit 1002 modules combined with one or more CPUs, supports cache coherence between the parallel processing unit 1002 modules and CPUs, and CPU mastering. Data and/or commands may be transmitted by the NVLink 1020 through the hub 1012 to/from other units of the parallel processing unit 1002 such as one or more copy engines, a video encoder, a video decoder, a power management unit, etc. (not explicitly shown).

The I/O unit 1004 is configured to transmit and receive communications (e.g., commands, data, etc.) from a host processor (not shown) over the interconnect 1022. The I/O unit 1004 may communicate with the host processor directly via the interconnect 1022 or through one or more intermediate devices such as a memory bridge. In an embodiment, the I/O unit 1004 may communicate with one or more other processors, such as one or more parallel processing unit 1002 modules via the interconnect 1022. In an embodiment, the I/O unit 1004 implements a Peripheral Component Interconnect Express (PCIe) interface for communications over a PCIe bus and the interconnect 1022 is a PCIe bus. In alternative embodiments, the I/O unit 1004 may implement other types of well-known interfaces for communicating with external devices.

The I/O unit 1004 decodes packets received via the interconnect 1022. In an embodiment, the packets represent commands configured to cause the parallel processing unit 1002 to perform various operations. The I/O unit 1004 transmits the decoded commands to various other units of the parallel processing unit 1002 as the commands may specify. For example, some commands may be transmitted to the front-end unit 1006. Other commands may be transmitted to the hub 1012 or other units of the parallel processing unit 1002 such as one or more copy engines, a video encoder, a video decoder, a power management unit, etc. (not explicitly shown). In other words, the I/O unit 1004 is configured to route communications between and among the various logical units of the parallel processing unit 1002.

In an embodiment, a program executed by the host processor encodes a command stream in a buffer that provides workloads to the parallel processing unit 1002 for processing. A workload may comprise several instructions and data to be processed by those instructions. The buffer is a region in a memory that is accessible (e.g., read/write) by both the host processor and the parallel processing unit 1002. For example, the I/O unit 1004 may be configured to access the buffer in a system memory connected to the interconnect 1022 via memory requests transmitted over the interconnect 1022. In an embodiment, the host processor writes the command stream to the buffer and then transmits a pointer to the start of the command stream to the parallel processing unit 1002. The front-end unit 1006 receives pointers to one or more command streams. The front-end unit 1006 manages the one or more streams, reading commands from the streams and forwarding commands to the various units of the parallel processing unit 1002.

The front-end unit 1006 is coupled to a scheduler unit 1008 that configures the various general processing cluster 1016 modules to process tasks defined by the one or more streams. The scheduler unit 1008 is configured to track state information related to the various tasks managed by the scheduler unit 1008. The state may indicate which general processing cluster 1016 a task is assigned to, whether the task is active or inactive, a priority level associated with the task, and so forth. The scheduler unit 1008 manages the execution of a plurality of tasks on the one or more general processing cluster 1016 modules.

The scheduler unit 1008 is coupled to a work distribution unit 1010 that is configured to dispatch tasks for execution on the general processing cluster 1016 modules. The work distribution unit 1010 may track a number of scheduled tasks received from the scheduler unit 1008. In an embodiment, the work distribution unit 1010 manages a pending task pool and an active task pool for each of the general processing cluster 1016 modules. The pending task pool may comprise a number of slots (e.g., 32 slots) that contain tasks assigned to be processed by a particular general processing cluster 1016. The active task pool may comprise a number of slots (e.g., 4 slots) for tasks that are actively being processed by the general processing cluster 1016 modules. As a general processing cluster 1016 finishes the execution of a task, that task is evicted from the active task pool for the general processing cluster 1016 and one of the other tasks from the pending task pool is selected and scheduled for execution on the general processing cluster 1016. If an active task has been idle on the general processing cluster 1016, such as while waiting for a data dependency to be resolved, then the active task may be evicted from the general processing cluster 1016 and returned to the pending task pool while another task in the pending task pool is selected and scheduled for execution on the general processing cluster 1016.

The work distribution unit 1010 communicates with the one or more general processing cluster 1016 modules via crossbar 1014. The crossbar 1014 is an interconnect network that couples many of the units of the parallel processing unit 1002 to other units of the parallel processing unit 1002. For example, the crossbar 1014 may be configured to couple the work distribution unit 1010 to a particular general processing cluster 1016. Although not shown explicitly, one or more other units of the parallel processing unit 1002 may also be connected to the crossbar 1014 via the hub 1012.

The tasks are managed by the scheduler unit 1008 and dispatched to a general processing cluster 1016 by the work distribution unit 1010. The general processing cluster 1016 is configured to process the task and generate results. The results may be consumed by other tasks within the general processing cluster 1016, routed to a different general processing cluster 1016 via the crossbar 1014, or stored in the memory 1024. The results can be written to the memory 1024 via the memory partition unit 1018 modules, which implement a memory interface for reading and writing data to/from the memory 1024. The results can be transmitted to another parallel processing unit 1002 or CPU via the NVLink 1020. In an embodiment, the parallel processing unit 1002 includes a number U of memory partition unit 1018 modules that is equal to the number of separate and distinct memory 1024 devices coupled to the parallel processing unit 1002.

In an embodiment, a host processor executes a driver kernel that implements an application programming interface (API) that enables one or more applications executing on the host processor to schedule operations for execution on the parallel processing unit 1002. In an embodiment, multiple compute applications are simultaneously executed by the parallel processing unit 1002 and the parallel processing unit 1002 provides isolation, quality of service (QoS), and independent address spaces for the multiple compute applications. An application may generate instructions (e.g., API calls) that cause the driver kernel to generate one or more tasks for execution by the parallel processing unit 1002. The driver kernel outputs tasks to one or more streams being processed by the parallel processing unit 1002. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory.

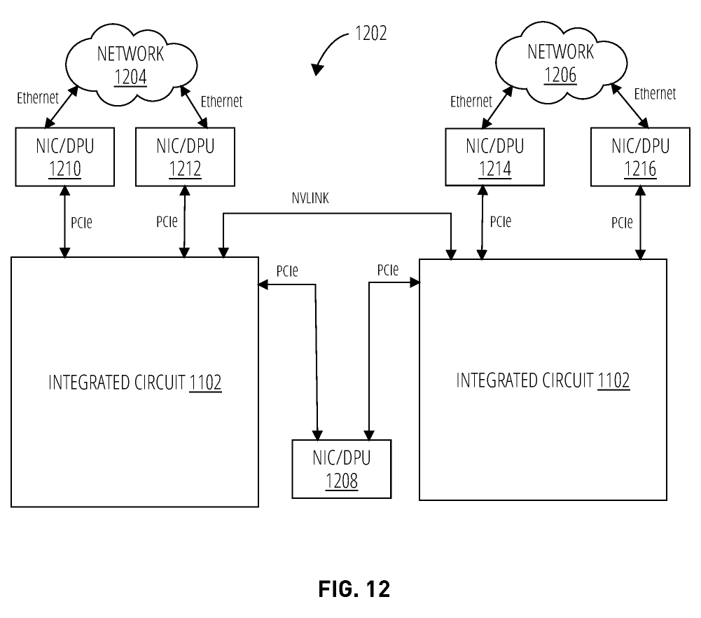

FIG. 12 is a block diagram of a computing system 1202 having two processing devices coupled to each other and to multiple networks 1204, 1206 according to at least one embodiment. The computing system 1202 is designed with multiple integrated circuits integrated circuits 1102 (referred to as processing devices), where each integrated circuit includes a central processing unit 1104 and two (or more) graphics processing units 1106, 1108, forming a powerful and flexible architecture. These processing devices may be interconnected via an NVLink (or other high-speed interconnect), enabling high-speed communication between the processing devices 1102, and may also communicate through a Network Interface Card (NIC) or Data Processing Unit (DPU) 1208 to enable efficient data transfer across the computing system 1202. In some embodiments, aspects of the mechanisms disclosed herein may be implemented in a DPU or NIC.

The cooling mechanisms described herein may be utilized to cool the integrated circuits 1102 and/or any one or more of the components of the integrated circuits 1102 (e.g., the central processing unit 1104 or graphics processing units 1106, 1108).

A NIC and a DPU may serve different roles in network architecture, despite both facilitating network connectivity. A NIC may primarily provide a hardware interface to connect elements of a computing system to a network. A NIC may handle basic network communication tasks such as formatting, sending, and receiving data packets. The processing capabilities of a NIC may be limited to traditional network processing tasks.

A DPU comprises a specialized processing unit designed to offload and accelerate complex data processing tasks from the NIC or computing system. A NIC may combine a network interface, programmable processing, and storage capabilities and may perform tasks such as security, storage virtualization, and network telemetry.

The coupling of the processing devices 1102 via NVLink enables data exchange and parallel processing, enhancing overall computational performance. A computing system 1202 configured in this manner may process complex, multi-network tasks with high bandwidth and low latency. This configuration makes the computing system 1202 suitable for demanding applications that consume significant processing power by current standards, such as artificial intelligence (AI), machine learning (ML), and data-intensive computing, while providing robust connectivity and scalability across various networked environments.

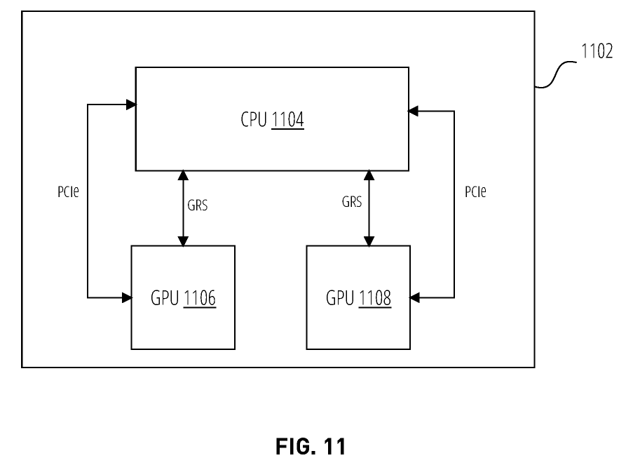

As depicted in the example embodiment of FIG. 11, the central processing unit 1104 may be coupled to the graphics processing units 1106, 1108 via a die-to-die (D2D) or chip-to-chip (C2C) interconnect such as a Ground-Referenced Signaling interconnect (GRS interconnect). The central processing unit 1104 may be coupled to the graphics processing units 1106, 1108 via PCIe (Peripheral Component Interconnect Express) interconnects.

The central processing unit 1104 component of the integrated circuit 1102 may be coupled to one or more network interface cards (NICs) or data processing units (DPUs), and these may be coupled to one or more networks. For example, as depicted in FIG. 12, the central processing unit 1104 component of one of the integrated circuits 1102 may be coupled to a network 1204 via a pair of NICs or DPUs 1210, 1212. The NICs or DPUs 1210, 1212 may be coupled to the network 1204 in a number of ways, for example over Ethernet (ETH), NVLINK, or InfiniBand (IB) connections. Likewise, the central processing unit 1104 component of the other integrated circuit 1102 may be coupled to a network 1206 via a pair of NICs or DPUs 1214, 1216, and the NICs or DPUs 1214, 1216 may be coupled to the network 1206 for example over Ethernet (ETH), NVLINK, or InfiniBand (IB) connections, for example.

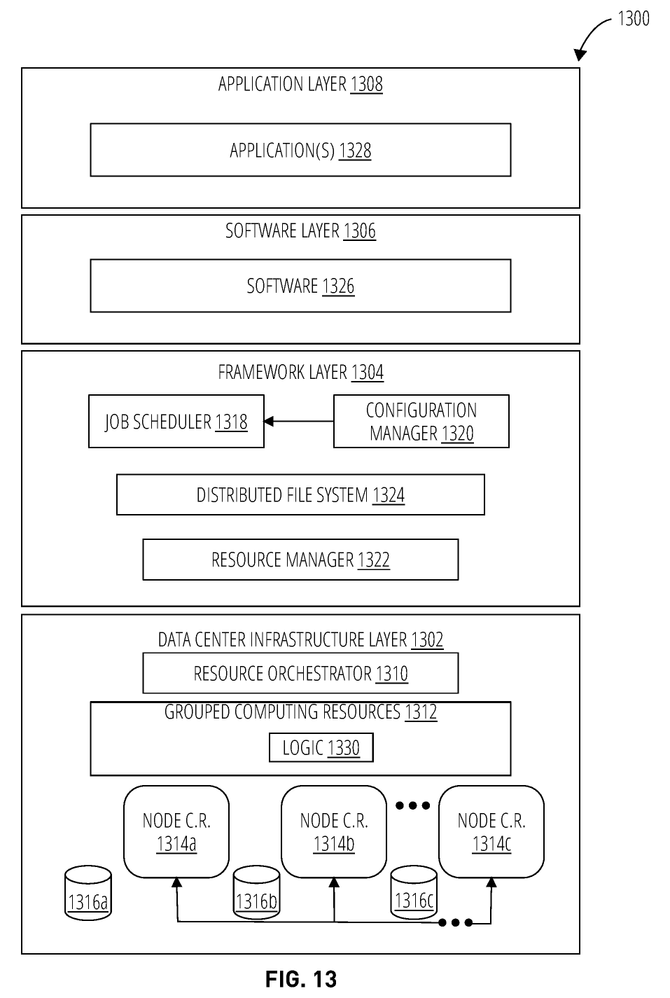

FIG. 13 depicts an exemplary data center 1300, in accordance with at least one embodiment. In at least one embodiment, data center 1300 includes, without limitation, a data center infrastructure layer 1302, a framework layer 1304, a software layer 1306, and an application layer 1308. The cooling mechanisms disclosed herein may be utilized to cool integrated circuits utilized the data center 1300.

In at least one embodiment, as depicted in FIG. 13, data center infrastructure layer 1302 may include a resource orchestrator 1310, grouped computing resources 1312, and node computing resources (node C.R.s) 1314a, 1314b, 1314c, where “N” represents any whole, positive integer. In at least one embodiment, node computing resources may include, but are not limited to, any number of central processing units (CPUs) or other processors (including accelerators, field programmable gate arrays (FPGAs), graphics processors, etc.), memory devices 1316a, 1316b, 1316c (e.g., dynamic random-access memory, solid state or disk drives, etc.), network input/output (NW I/O) devices, network switches, virtual machines (VMs), power modules, and cooling modules, etc. In at least one embodiment, one or more node computing resources from among node computing resources 1314a, 1314b, 1314c may be a server having one or more of the above-mentioned computing resources.

In at least one embodiment, grouped computing resources 1312 may include separate groupings of node computing resources housed within one or more racks (not shown), or many racks housed in data centers at various geographical locations (also not shown). Separate groupings of node computing resources within grouped computing resources 1312 may include grouped compute network, memory, or storage resources that may be configured or allocated to support one or more workloads. In at least one embodiment, several node computing resources including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 1310 may configure or otherwise control one or more node computing resources 1314a, 1314b, 1314c and/or grouped computing resources 1312. In at least one embodiment, resource orchestrator 1310 may include a software design infrastructure (“SDI”) management entity for data center 1300. In at least one embodiment, resource orchestrator 1310 may include hardware, software, or some combination thereof.

In at least one embodiment, as depicted in FIG. 13, framework layer 1304 includes, without limitation, a job scheduler 1318, a configuration manager 1320, a resource manager 1322, and a distributed file system 1324. In at least one embodiment, framework layer 1304 may include a framework to support software 1326 of software layer 1306 and/or one or more application(s) 1328 of application layer 220. In at least one embodiment, software 1326 or application(s) 1328 may respectively include web-based service software or applications, such as those provided by Amazon Web Services, Google Cloud, and Microsoft Azure. In at least one embodiment, framework layer 1304 may be, but is not limited to, a type of free and open-source software web application framework such as Apache SPARK^{TM} (hereinafter “Spark) that may utilize a distributed file system 1324 for large-scale data processing (e.g., “big data”). In at least one embodiment, job scheduler 1318 may include a Spark driver to facilitate scheduling of workloads supported by various layers of data center 1300. In at least one embodiment, configuration manager 1320 may be capable of configuring different layers such as software layer 1306 and framework layer 1304, including Spark and distributed file system 1324 for supporting large-scale data processing. In at least one embodiment, resource manager 1322 may be capable of managing clustered or grouped computing resources mapped to or allocated for support of distributed file system 1324 and job scheduler 1318. In at least one embodiment, clustered or grouped computing resources may include grouped computing resources 1312 at data center infrastructure layer 1302. In at least one embodiment, resource manager 1322 may coordinate with resource orchestrator 1310 to manage these mapped or allocated computing resources.

In at least one embodiment, software 1326 included in software layer 1306 may include software used by at least portions of node computing resources 1314a, 1314b, 1314c, grouped computing resources 1312, and/or distributed file system 1324 of framework layer 1304. One or more types of software may include, but are not limited to, Internet web page search software, e-mail virus scan software, database software, and streaming video content software.

In at least one embodiment, application(s) 1328 included in application layer 1308 may include one or more types of applications used by at least portions of node computing resources 1314a, 1314b, 1314c, grouped computing resources 1312, and/or distributed file system 1324 of framework layer 1304. In at least one or more types of applications may include, without limitation, Compute Unified Device Architecture (CUDA) applications, 5G network applications, artificial intelligence applications, data center applications, and/or variations thereof. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 1320, resource manager 1322, and resource orchestrator 1310 may implement any number and type of self-modifying actions based on any amount and type of data acquired in any technically feasible fashion. In at least one embodiment, self-modifying actions may relieve a data center operator of data center 1300 from making possibly bad configuration decisions and possibly avoiding underutilized and/or poorly performing portions of a data center.

In at least one embodiment, data center 1300 may comprise tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 1300. In at least one embodiment, trained machine learning models corresponding to one or more neural networks may be used to infer or predict information using resources described above with respect to data center 1300by using weight parameters calculated through one or more training techniques described herein.

In at least one embodiment, data center 1300 may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

The grouped computing resources 1312 may be configured with logic 1330 to implement the application(s) 1328. For example, the logic 1330 may comprise inference and/or training logic to perform deep learning inferencing and/or training operations associated with one or more embodiments. In at least one embodiment, logic 1330 may configure the data center 1300 for inferencing or predicting operations based, at least in part, on weight parameters calculated using neural network training operations, neural network functions and/or architectures, or neural network use cases described herein.

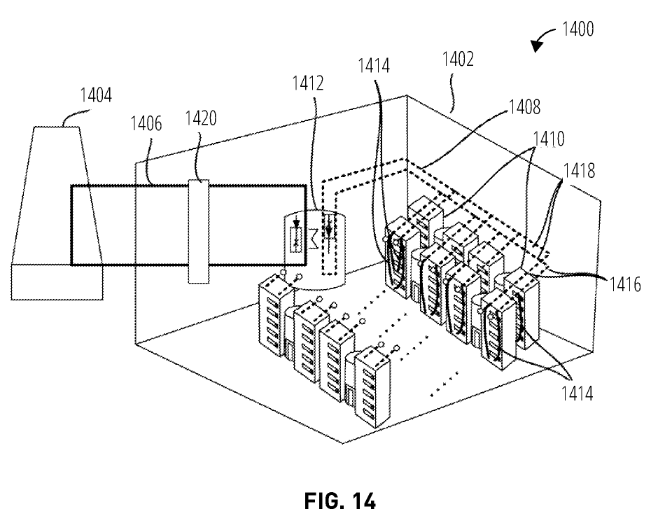

In at least one embodiment, an exemplary data center 1400 may be configured as depicted in FIG. 14. The data center 1400 utilizes may a cooling system comprising embodiments of the cooling systems and apparatuses described herein.

The data center 1400 may comprise one or more partitions 1402 each comprising multiple racks 1410, and auxiliary equipment to house one or more server machines disposed on one or more server trays.

The data center 1400 may utilize a cooling tower 1404 located external to or internal to the data center 1400. The cooling tower 1404 may dissipate heat generated within the data center 1400 by acting on a primary cooling loop 1406. A cooling distribution unit 1412 (CDU) may be disposed between a primary cooling loop 1406 and a second or secondary cooling loop 1408 to enable transfer of heat between the cooling loops 1406, 1408. The secondary cooling loop 1408 may traverse various plumbing into the server trays as required.

The cooling loops 1406, 1408 are depicted in line drawing, but a person of ordinary skill would recognize that one or more plumbing features not depicted may be utilized. In one embodiment, flexible polyvinyl chloride (PVC) pipes may be utilized along with associated plumbing to move fluid along in each cooling loop 1406, 1408. One or more coolant pumps (not depicted) may be operated to maintain pressure differences within cooling loops 1406, 1408 to enable movement of coolant according to temperature sensors in various locations, including in a particular partition, in one or more of the racks 1410, and/or in one or more server boxes or server trays within one or more racks 1410.

In one implementation, coolant in the primary cooling loop 1406 and in the secondary cooling loop 1408 may be at least water, optionally including an additive such as glycol or propylene glycol. In operation, in at least one embodiment, each of the cooling loops 1406, 1408 may comprise segregated coolant from the other. The coolant utilized in the secondary cooling loop 1408 may be proprietary to requirements of components in a server tray or in associated racks 1410.

In at least one embodiment, the cooling distribution unit 1412 is enabled with sophisticated control of coolant materials, independently or concurrently, within the cooling loops 1406, 1408. The cooling distribution unit 1412 may be adapted to control flow rate of coolant so that coolant is appropriately distributed to absorb heat generated within associated racks 1410. Flexible manifold tubing 1414 may be provided from a secondary cooling loop 1408 into each server tray to provide coolant to electrical and/or computing components therein.

Manifold tubing 1418 that forms part of the secondary cooling loop 1408 may be referred to as room manifolds. In some embodiments, additional manifold tubing 1416 may extend from the manifold tubing 1418 and may as part of the secondary cooling loop 1408, and may be referred to as row manifolds. The manifold tubing 1414 may enter the racks 1410 from the secondary cooling loop 1408 and may be referred to as a rack cooling manifold.

The row manifold tubing 1416 may extend to all racks along a row in the data center 1400. Plumbing of the secondary cooling loop 1408, including coolant manifolds 1418, 1416, and 1414, may utilize at least one embodiment in accordance with the cooling apparatuses disclosed herein.

A chiller 1420 may be provided in the cooling loop 1406 within the partitions 1402 to support cooling before coolant reaches the cooling tower 1404. Additional cooling loops may exist in the primary control cooling loop 1406 to provide cooling external to a rack and external to the secondary cooling loop 1408.

In operation, heat generated within server trays of the racks 1410 may be transferred to a coolant exiting one or more of the racks 1410 via flexible tubing of a row manifold tubing 1414 of the second cooling loop 1408. Second coolant (in a secondary cooling loop 1408 as distinct from first coolant in a primary cooling loop 1406) from the cooling distribution unit 1412 for cooling provided racks 1410 may move towards one or more of the racks 1410 via the provided tubing.

The second coolant from the cooling distribution unit 1412 may pass from on one side of a room manifold comprising manifold tubing 1418, to one side of a rack 1410 via a row manifold tubing 1416, and through one side of a server tray via different the manifold tubing 1414. Spent or returned second coolant (or exiting second coolant carrying heat from computing components) may exit out of another side of a server tray, such as enter left side of a rack and exits right side of a rack 1410 for a server tray after looping through a server tray or through components on a server tray. Spent second coolant that exits a server tray or a rack 1410 may exit a different side (such as exiting side) of the manifold tubing 1414 and move to a parallel, but also exiting side, of the row manifold tubing 1416.

From a row manifold 1416, spent second coolant may move in a parallel portion of the room manifold tubing 1418 going in an opposite direction than incoming second coolant (which may also be renewed second coolant), towards the cooling distribution unit 1412.

Spent second coolant may exchange heat to a first e.g., primary coolant in the primary cooling loop 1406 via the cooling distribution unit 1412. Spent second coolant may be renewed (such as relatively cooled when compared to a temperature at a spent second coolant stage) and cycled back to through the secondary cooling loop 1408 to one or more computing components.

Various flow and temperature control features of the cooling distribution unit 1412 may enable control of heat exchanged from spent second coolant or flow of second coolant in and out of the cooling distribution unit 1412. The cooling distribution unit 1412 may be enabled to control a flow of primary coolant in the primary cooling loop 1406.

### LISTING OF DRAWING ELEMENTS

102 system memory

104 device driver

106 memory bridge

108 central processing unit

110 parallel processing subsystem

112 display device

114 input/output bridge

116 system disk

118 switch

120 add-in card

122 add-in card

124 network adapter

126 input devices

128 communication path

130 computer system

132 communication path

200 server machine

201 enclosure

210 motherboard

211 central processing unit

212 memory device

220 graphics card

221 backplane

230 thermal mitigation component

231 cold plate

232 intake cooling liquid line

233 cold plate

234 intake cooling liquid line

235 manifold

236 outtake cooling liquid line

238 outtake cooling liquid line

302 vapor chamber

304 internal volume

306 vapor conduit

308 cold plate

310 integrated circuit

312 mounting substrate

402 bottom micro-channel array

404 top micro-channel array

406 heat dissipating elements

408 section

702 internal fluid outlet

704 external fluid outlet port

706 base manifold

708 top manifold

710 external fluid inlet port

712 internal fluid inlet

802 flow plate

804 bottom flow plate

806 inlet manifold

808 outlet manifold

810 flow-through hole

812 flow divider

814 flow channels

816 bottom flow divider

1002 parallel processing unit

1004 I/O unit

1006 front-end unit

1008 scheduler unit

1010 work distribution unit

1012 hub

1014 crossbar

1016 general processing cluster

1018 memory partition unit

1020 NVLink

1022 interconnect

1024 memory

1102 integrated circuit

1104 central processing unit

1106 graphics processing unit

1108 graphics processing unit

1202 computing system

1204 network

1206 network

1208 NIC or DPU

1210 NIC or DPU

1212 NIC or DPU

1214 NIC or DPU

1216 NIC or DPU

1300 data center

1302 data center infrastructure layer

1304 framework layer

1306 software layer

1308 application layer

1310 resource orchestrator

1312 grouped computing resources

1314a node computing resource

1314b node computing resource

1314c node computing resource

1316a memory device

1316b memory device

1316c memory device

1318 job scheduler

1320 configuration manager

1322 resource manager

1324 distributed file system

1326 software

1328 application(s)

1330 logic

1400 data center

1402 partitions

1404 cooling tower

1406 cooling loop

1408 cooling loop

1410 racks

1412 cooling distribution unit

1414 manifold tubing

1416 manifold tubing

1418 manifold tubing

1420 chiller

Within this disclosure, different entities (which may variously be referred to as "units," "circuits," other components, etc.) may be described or claimed as "configured" to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be "configured to" perform some task even if the structure is not currently being operated. The term "configured to" is not intended to mean "configurable to."

Reciting in the appended claims that a structure is "configured to" perform one or more tasks is expressly intended not to invoke 35 U.S.C. § 112(f) for that claim element. Accordingly, claims in this application that do not otherwise include the "means for" [performing a function] construct should not be interpreted under 35 U.S.C § 112(f).

As used herein, the term "based on" is used to describe one or more factors that affect a determination. This term does not foreclose the possibility that additional factors may affect the determination. That is, a determination may be solely based on specified factors or based on the specified factors as well as other, unspecified factors. Consider the phrase "determine A based on B." This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase "based on" is synonymous with the phrase "based at least in part on."

As used herein, the phrase "in response to" describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase "perform A in response to B." This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms "first," "second," etc. are used as labels for nouns that they precede, and do not imply any type of ordering (e.g., spatial, temporal, logical, etc.), unless stated otherwise. For example, in a register file having eight registers, the terms "first register" and "second register" can be used to refer to any two of the eight registers, and not, for example, just logical registers 0 and 1.

When used in the claims, the term "or" is used as an inclusive or and not as an exclusive or. For example, the phrase "at least one of x, y, or z" means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended disclosure as claimed. The scope of inventive subject matter is not limited to the depicted embodiments but is rather set forth in the following Claims.

### LISTING OF DRAWING ELEMENTS

102 vapor chamber

104 internal volume

106 vapor conduit

108 cold plate

110 integrated circuit

112 mounting substrate

202 bottom micro-channel array

204 top micro-channel array

206 heat dissipating elements

208 section

502 internal fluid outlet

504 external fluid outlet port

506 base manifold

508 top manifold

510 external fluid inlet port

512 internal fluid inlet

602 flow plate

604 bottom flow plate

606 inlet manifold

608 outlet manifold

610 flow-through hole

612 flow divider

614 flow channels

616 bottom flow divider

802 parallel processing unit

804 I/O unit

806 front-end unit

808 scheduler unit

810 work distribution unit

812 hub

814 crossbar

816 general processing cluster

818 memory partition unit

820 NVLink

822 interconnect

824 memory

902 integrated circuit

904 central processing unit

906 graphics processing unit

908 graphics processing unit

1002 computing system

1004 network

1006 network

1008 NIC or DPU

1010 NIC or DPU

1012 NIC or DPU

1014 NIC or DPU

1016 NIC or DPU

1100 data center

1102 data center infrastructure layer

1104 framework layer

1106 software layer

1108 application layer

1110 resource orchestrator

1112 grouped computing resources

1114a node computing resource

1114b node computing resource

1114c node computing resource

1116a memory device

1116b memory device

1116c memory device

1118 job scheduler

1120 configuration manager

1122 resource manager

1124 distributed file system

1126 software

1128 application(s)

1130 logic

1202 system memory

1204 device driver

1206 memory bridge

1208 central processing unit

1210 parallel processing subsystem

1212 display device

1214 input/output bridge

1216 system disk

1218 switch

1220 add-in card

1222 add-in card

1224 network adapter

1226

1228

1230 input devices

1232 communication path

1234 computer system

1236 communication path

What is claimed is:

1. A cooling apparatus comprising:
a vapor chamber comprising a lower portion, and upper portion, and a vapor conduit configured to enable a convection flow of vapor from the lower portion to the upper portion;
a first heat exchanger thermally coupled to the lower portion of the vapor chamber; and
a second heat exchanger thermally coupled to the upper portion of the vapor chamber.

2. The apparatus of claim 1, wherein the vapor chamber is formed into a U-shape.

3. The apparatus of claim 1, wherein the first heat exchanger comprises a greater surface area than a surface area of the second heat exchanger.

4. The apparatus of claim 1, further comprising a plurality of inlet ports, the inlet ports formed with a flattened cross-section.

5. The apparatus of claim 1, further comprising a plurality of outlet ports, the outlet ports formed with a flattened cross-section.

6. The apparatus of claim 1, further comprising a cold plate.

7. The apparatus of claim 6, wherein the cold plate comprises a top manifold, a base manifold, and a top flow plate and a bottom flow plate disposed between the top manifold and the base manifold.

8. The apparatus of claim 7, wherein the top flow plate comprises flow-through holes configured to direct coolant to the second heat exchanger.

9. The apparatus of claim 7, wherein the bottom flow plate comprises flow-through holes configured to direct coolant to the first heat exchanger.

10. The apparatus of claim 7, further comprising a first flow divider for the top flow plate and a second flow divider for the bottom flow plate.

11. An assembly comprising:
a data processor;
a cooling apparatus in thermal contact with the data processor, the cooling apparatus comprising:
a vapor chamber comprising a plurality of portions;
at least one vapor conduit configured to enable a convection flow of vapor from the lower portion to the upper portion;
a first heat exchanger thermally coupled to the lower portion of the vapor chamber; and
a second heat exchanger thermally coupled to the upper portion of the vapor chamber.

12. The assembly of claim 11, wherein the data processor is a central processing unit.

13. The assembly of claim 11, wherein the data processor is a graphics processing unit.

14. The assembly of claim 13, wherein the graphics processing unit is in direct thermal contact with the lower portion of the vapor chamber.

15. The assembly of claim 11, wherein the data processor is an integrated circuit comprising at least one central processing unit and at least one graphics processing unit.

16. A data center comprising:
a computing system each comprising one or more data processors;
a cooling apparatus thermally coupled to the one or more data processors, the cooling apparatus configured to:
receive fluid at an inlet manifold;
direct the fluid from the inlet manifold to a lower portion of a vapor chamber that is in direct thermal contact with the one or more data processor;
enable a convection flow of vapor from the lower portion of the vapor chamber to an upper portion of the vapor chamber;
direct the fluid through a first heat exchanger thermally coupled to the lower portion of the vapor chamber; and
direct the fluid through a second heat exchanger thermally coupled to the upper portion of the vapor chamber.

17. The data center of claim 16, wherein the inlet manifold comprises:
a plurality of intake ports each comprising a cross-section that does not extend beyond a height of the inlet manifold.

18. The data center of claim 16, further comprising an outlet manifold comprising a plurality of outlet ports each comprising a cross-section that does not extend beyond a height of the outlet manifold.

19. An assembly comprising:
an integrated circuit comprising at least one central processing unit and a plurality of graphics processing units;
a cooling apparatus in thermal contact with the integrated circuit, the cooling apparatus comprising:
a vapor chamber comprising a plurality of portions, each portion comprising a cooling surface;
at least one conduit for vapor convection and fluid return between the portions; and
wherein the cooling surface of each portion comprises a heat exchanger.

20. An apparatus for cooling integrated circuits, the apparatus comprising:
a vapor chamber comprising an upper portion and a lower portion, each portion comprising a cooling surface;
a conduit for vapor convection and fluid return between the upper portion and the lower portion; and
each cooling surface comprising an arrangement of metallic fins.
